(19) United States
(12) Patent Application Publication
(10) Pub. No.: US 2017/0079392 A1
(43) Pub. Date: Mar. 23, 2017

(54) Protective Case for Portable Electronic Device

(71) Applicant: Chia-Hao Lin, New Taipei City (TW)

(72) Inventor: Chia-Hao Lin, New Taipei City (TW)

(21) Appl. No.: 14/862,167

(22) Filed: Sep. 23, 2015

(51) Int. Cl. A45C 11/00; H05K 5/03

(52) U.S. Cl. CPC A45C 11/00; H05K 5/03; A45C 2011/002; A45C 2011/003

(57) ABSTRACT

A protective case for a portable electronic device includes a base and a cover. The base has an accommodation portion. One side of the base is formed with a connecting groove. The cover includes an inner decorative part, an outer decorative part, and a transparent plate. The inner decorative part has an inner side frame with an inner connecting piece. The outer decorative part has with an outer connecting piece. The inner and outer decorative parts are attached to two sides of the base, respectively. The transparent plate is disposed between the inner decorative part and the outer decorative part. The transparent plate has a protruding portion extending from the periphery of the transparent plate. The protruding portion is thinner than the transparent plate to form a stepped side. The inner side frame of the inner decorative part is attached to the stepped side of the protruding portion.

### NOTICE OF COPYRIGHT

A portion of the disclosure of this patent document contains material which is subject to copyright protection. The copyright owner has no objection to any reproduction by anyone of the patent disclosure, as it appears in the United States Patent and Trademark Office patent files or records, but otherwise reserves all copyright rights whatsoever.

### BACKGROUND OF THE PRESENT INVENTION

1. Field of Invention

The present invention relates to a protective case for a portable electronic device, and more particularly to a protective case combined with a transparent plate for protecting a portable electronic device and its screen from being scraped.

2. Description of Related Arts

With the development and improvement of technology, wired or wireless communication quality is also upgraded. Many portable electronic devices (such as mobile phones, tablet computers, notebook computers, and the like) are also innovated. The electronic devices are very popular and often taken along for use. When the portable electronic device having a screen is used, the screen of the portable electronic device may be scraped or damaged when it is rubbed by metallic articles (such as keys, key rings, coins, etc.) or falls down. The appearance of the surface of the product is damaged accordingly. In order to protect the screen from being scraped by an external force, a screen protective film is provided and attached to the screen, avoiding a hard article from touching the screen directly. In order to protect the surface of the portable electronic device from being worn or hit, there are many protective cases developed on the market. The user has to purchase the screen protective film and the protective case for the portable electronic device to be protected completely, but it will be a burden for the user.

### SUMMARY OF THE PRESENT INVENTION

The primary object of the present invention is to provide a flip-type protective case having a hard transparent plate. The transparent plate can be tightly attached to the screen of a portable electronic device. There is no need to lift the cover of the protective case. The user can directly touch the screen of the portable electronic device through the transparent plate. The present invention saves the cost and is convenient for use.

In order to achieve the object, the protective case of the present invention comprises a base and a cover. The base has an accommodation portion. The cover comprises an inner decorative part, an outer decorative part, and a transparent plate. The inner decorative part has an inner side frame. One side of the inner side frame is provided with an inner connecting piece. The outer decorative part corresponds in shape to the inner decorative part. The outer decorative part has an outer side frame. One side of the outer side frame is provided with an outer connecting piece. The inner decorative part is laminated with the outer decorative part. The inner decorative part and the outer decorative part are attached to one side of the base, respectively. The transparent plate is disposed between the inner decorative part and the outer decorative part. The transparent plate has a protruding portion extending from the periphery of the transparent plate. The protruding portion is thinner than the transparent plate to form a stepped side. The inner side frame of the inner decorative part is attached to the stepped side of the protruding portion. The inner side frame is flush with the transparent plate. The outer side frame of the outer decorative part is attached to another side of the protruding portion.

In one embodiment of the present invention, the side of the base is formed with a connecting groove. The inner decorative part and the outer decorative part are attached to two sides of the connecting groove, respectively.

In one embodiment of the present invention, the connecting groove has a thickness less than that of the base, and the two side of the connecting groove are formed with steps.

In one embodiment of the present invention, the inner connecting piece and the outer connecting piece are flush with the base, respectively.

In one embodiment of the present invention, the inner decorative part has an inner through hole at a central portion thereof, and the outer decorative part has an outer through hole at a central portion thereof.

In one embodiment of the present invention, the transparent plate comprises an inner plate and an outer plate which are attached to each other.

In one embodiment of the present invention, the inner plate has a length and a width less than those of the outer plate, such that the transparent plate is formed with a stepped portion around the outer periphery thereof.

In one embodiment of the present invention, the transparent plate is made of acryl or tempered glass.

According to the aforesaid structure, the transparent plate and the protective case are combined to be one-piece. The user can directly watch/touch the screen of the portable electronic device through the transparent plate. The present invention saves the cost and is convenient for use.

### BRIEF DESCRIPTION OF THE DRAWINGS

FIG. 1 is an exploded view of the present invention;

FIG. 2 is a perspective view of the present invention;

FIG. 3 is a sectional view of the present invention;

FIG. 4 is an exploded view of another embodiment of the transparent plate of the present invention; and

FIG. 5 is a perspective view of FIG. 4.

### DETAILED DESCRIPTION OF THE PREFERRED EMBODIMENT

Embodiments of the present invention will now be described, by way of example only, with reference to the accompanying drawings.

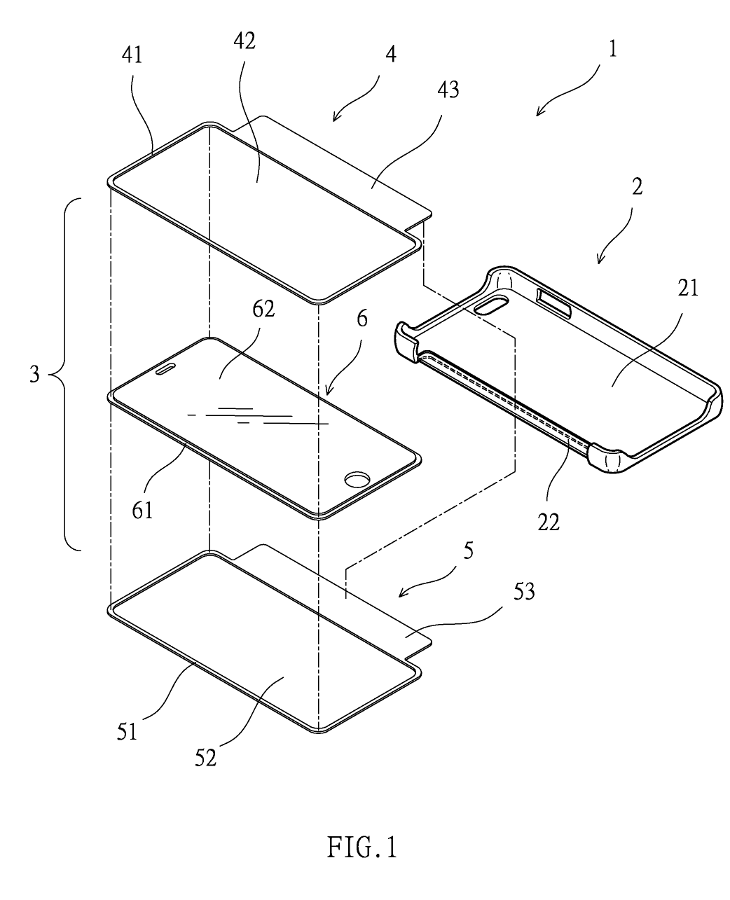

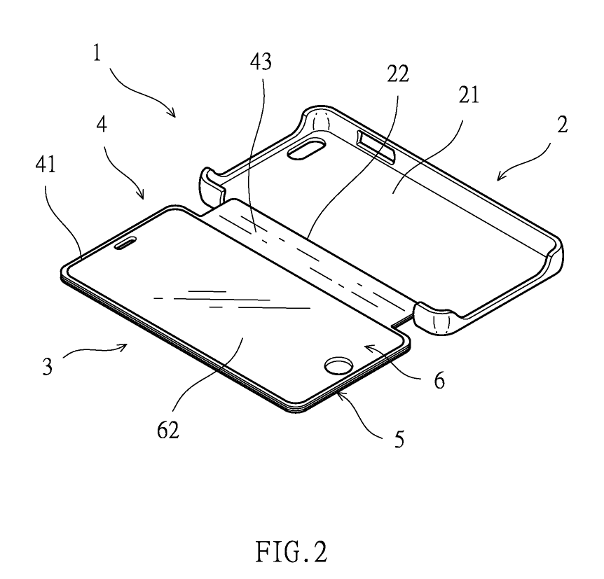

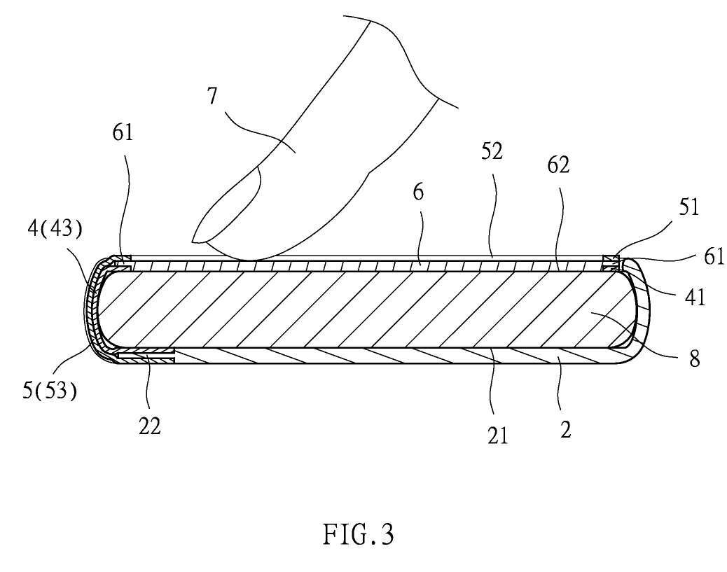

As shown in FIG. 1 through FIG. 3, a protective case 1 comprises a base 2 and a cover 3. The base 2 has an accommodation portion 21 for accommodating a portable electronic device 8. One side of the base 2 is formed with a connecting groove 22. The connecting groove 22 has a thickness less than that of the base 2, such that steps are formed between upper and lower surfaces of the connecting groove 22 and upper and lower surfaces of the base 2.

The cover 3 comprises an inner decorative part 4, an outer decorative part 5, and a transparent plate 6. The inner decorative part 4 has an inner side frame 41 to surround an inner through hole 42 at a central portion thereof. One side of the inner side frame 41 is provided with an inner connecting piece 43. The outer decorative part 5 corresponds in shape to the inner decorative part 4. The outer decorative part 5 has an outer side frame 51 to surround an outer through hole 52 at a central portion thereof. One side of the outer side frame 51 is provided with an outer connecting piece 53. The inner decorative part 4 is laminated with the outer decorative part 5. The inner decorative part 4 and the outer decorative part 5 are attached to two sides of the connecting groove 22 of the base 2, respectively. The inner connecting piece 43 and the outer connecting piece 53 are flush with the base 2. The transparent plate 6 is disposed between the inner decorative part 4 and the outer decorative part 5. The transparent plate 6 has a protruding portion 61 extending from the periphery of the transparent plate 6. The protruding portion 61 is thinner than the transparent plate 6 to form a stepped side. The inner side frame 41 of the inner decorative part 4 is attached to the stepped side of the protruding portion 61, and the inner side frame 41 is flush with the transparent plate 6 to form a contact surface 62.

The outer side frame 51 of the outer decorative part 5 is attached to another side of the protruding portion 61.

According to the aforesaid structure, the protective case 1 is combined with the transparent plate 6 to be one-piece. The cover 3 is adapted to cover the portable electronic device 8 accommodated in the base 2, such that the contact surface 62 of the transparent plate 6 is tightly attached to the screen of the portable electronic device 8. The user can see the transparent plate 6 by means of the outer through hole 52 of the outer decorative part 5 and the inner through hole 42 of the inner decorative part 4 so as to watch/touch the screen directly. The present invention saves the cost and is convenient for use.

The assembly and function of the aforesaid embodiment are described hereinafter. As shown in FIG. 1 through FIG. 3, the transparent plate 6 is made of acryl, tempered glass, or the like to form a hard plate for supporting and keeping the shape of the cover 3, preventing the cover 3 from deforming and protecting the screen of the portable electronic device 8 from being scraped or damaged. The base 2 is made of a resilient material, such as rubber, silica gel, plastic, metal, or a combination thereof. The contour of the base 2 is identical to the portable electronic device 8. By the resilient deformation capability of the base 2, the portable electronic device 8 is accommodated in the accommodation portion 21 of the base 2. The base 2 is formed with a plurality of holes corresponding to the sockets and buttons of the portable electronic device 8 for the portable electronic device 8 to be operated and used normally. Furthermore, the inner decorative part 4 and the outer decorative part 5 are made of leather, synthetic leather, fabric, rubber, silica gel, plastic, or a combination thereof, enabling the integral inner connecting piece 43 and the outer connecting piece 53 to be curved, such that the cover 3 can be opened or closed relative to the base 2.

As shown in FIG. 1 through FIG. 3, after the transparent plate 6 and the inner side frame 41 of the inner decorative part 4 of the present invention are combined together, the step formed by the protruding portion 61 of the transparent plate 6 makes the inner side frame 41 not protrude out of the surface of the transparent plate 6. When the cover 3 is closed to cover the screen of the portable electronic device 8, the transparent plate 6 is tightly attached to the screen, not hindered by the inner side frame 41. This avoids a gap formed between the transparent plate 6 and the screen to cause a bad touch contact. Thus, there is no need to lift the cover 3 of the protective case 1. The transparent plate 6 is adapted for the user's finger to touch the screen externally and protects the screen from being scraped by an external force. The user doesn't have to purchase a protective case as well as a screen protective film. The present invention saves the cost and can be used conveniently.

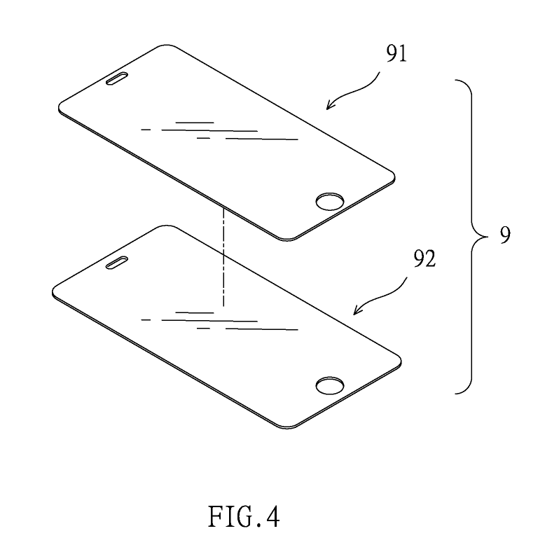

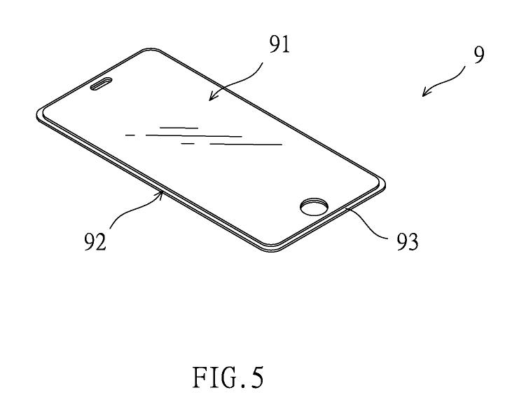

FIG. 4 and FIG. 5 show another embodiment of the transparent plate. A transparent plate 9 comprises an inner plate 91 and an outer plate 92 which are attached to each other. The inner plate 91 has a length and a width less than those of the outer plate 92, such that the transparent plate 9 is formed with a stepped portion 93 around an outer periphery thereof. When the transparent plate 9 is combined with the inner side frame 41 of the inner decorative part 4, the inner side frame 41 is flush with the transparent plate 9.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A protective case for a portable electronic device, comprising a base and a cover, the base having an accommodation portion; and
the cover comprising an inner decorative part, an outer decorative part, and a transparent plate;
wherein the inner decorative part has an inner side frame, and one side of the inner side frame is provided with an inner connecting piece;
wherein the outer decorative part corresponds in shape to the inner decorative part, the outer decorative part has an outer side frame, one side of the outer side frame is provided with an outer connecting piece, the inner decorative part is laminated with the outer decorative part, and the inner decorative part and the outer decorative part are attached to one side of the base, respectively;
wherein the transparent plate is disposed between the inner decorative part and the outer decorative part, the transparent plate has a protruding portion extending from a periphery of the transparent plate, the protruding portion is thinner than the transparent plate to form a stepped side, the inner side frame of the inner decorative part is attached to the stepped side of the protruding portion, the inner side frame is flush with the transparent plate, and the outer side frame of the outer decorative part is attached to another side of the protruding portion.

2. The protective case for a portable electronic device as claimed in claim 1, wherein the side of the base is formed with a connecting groove, and the inner decorative part and the outer decorative part are attached to two sides of the connecting groove, respectively.

3. The protective case for a portable electronic device as claimed in claim 2, wherein the connecting groove has a thickness less than that of the base, and the two side of the connecting groove are formed with steps.

4. The protective case for a portable electronic device as claimed in claim 3, wherein the inner connecting piece and the outer connecting piece are flush with the base, respectively.

5. The protective case for a portable electronic device as claimed in claim 1, wherein the inner decorative part has an inner through hole at a central portion thereof, and the outer decorative part has an outer through hole at a central portion thereof.

6. The protective case for a portable electronic device as claimed in claim 1, wherein the transparent plate comprises an inner plate and an outer plate which are attached to each other.

7. The protective case for a portable electronic device as claimed in claim 6, wherein the inner plate has a length and a width less than those of the outer plate, such that the transparent plate is formed with a stepped portion around an outer periphery thereof.

8. The protective case for a portable electronic device as claimed in claim 1, wherein the transparent plate is made of acryl or tempered glass.

9. The protective case for a portable electronic device as claimed in claim 6, wherein the transparent plate is made of acryl or tempered glass.
